(19) United States
(12) Patent Application Publication
(10) Pub. No.: US 2023/0411329 A1
(43) Pub. Date: Dec. 21, 2023

(54) Dielectric Blocking Layer and Method Forming the Same

(71) Applicant: Taiwan Semiconductor Manufacturing Co., Ltd., Hsinchu (TW)

(72) Inventors: Chih-Wei Wu, Zhuangwei Township (TW); Ying-Ching Shih, Hsinchu (TW); Wen-Chih Chiou, Zhunan Township (TW)

(21) Appl. No.: 17/929,180

(22) Filed: Sep. 1, 2022

Related U.S. Application Data
(60) Provisional application No. 63/366,438, filed on Jun. 15, 2022.

(51) Int. Cl. H01L 23/00

(52) U.S. Cl. CPC H01L 24/11; H01L 24/16; H01L 2224/11618; H01L 2224/16147; H01L 24/32; H01L 2224/32505; H01L 2224/0913; H01L 24/09; H01L 2224/08147; H01L 2224/08146; H01L 24/08; H01L 24/24; H01L 2224/24146; H01L 2924/3841; H01L 2924/37001

(57) ABSTRACT

A method includes forming a first package component, which comprises forming a first dielectric layer having a first top surface, and forming a first conductive feature. The first conductive feature includes a via embedded in the first dielectric layer, and a metal bump having a second top surface higher than the first top surface of the first dielectric layer. The method further includes dispensing a photo-sensitive layer, with the photo-sensitive layer covering the metal bump, and performing a photolithography process to form a recess in the photo-sensitive layer. The metal bump is exposed to the recess, and the photo-sensitive layer has a third top surface higher than the metal bump. A second package component is bonded to the first package component, and a solder region extends into the recess to bond the metal bump to a second conductive feature in the second package component.

### PRIORITY CLAIM AND CROSS-REFERENCE

This application claims the benefit of the following provisionally filed U.S. patent application: Application No. 63/366,438, filed on Jun. 15, 2022, and entitled “Ultra Fine Pitch Bump Interconnection,” which application is incorporated herein by reference.

### BACKGROUND

In the formation of integrated circuits, package components such as transistors are formed at the surface of a semiconductor substrate in a wafer. Metal bumps may be formed on the surface of the wafer. In a packaging process, top dies may be bonded to a bottom wafer through solder regions. The bottom wafer may then be sawed into dies. This formation process may incur difficulty with the reduction in the pitches of the metal bumps. For example, the likelihood of the solder bridging on neighboring metal bumps increases with the reduction of the pitches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 and 14A illustrate the cross-sectional views of intermediate stages in the formation of a package including sawed device dies in accordance with some embodiments.

FIG. 14B illustrates a cross-sectional view of a package including a reconstructed wafer in accordance with some embodiments.

FIG. 15 illustrates a cross-sectional view of a package in accordance with some embodiments.

FIG. 16 illustrates a top view of a package in accordance with some embodiments.

FIG. 17 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, the package includes a first package component (such as a device die) bonding to a second package component. The first package component includes a metal bump protruding beyond a surface dielectric layer of the first package component. A photo-sensitive polymer is then coated on the metal bump and the surface dielectric layer, and is then light-exposed and developed, so that a recess is formed in the photo-sensitive polymer to reveal the metal bump. A solder region bonds the metal bump to the second package component. The recess is used for housing the solder region, and has the function of preventing the solder from bridging to neighboring solder regions. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

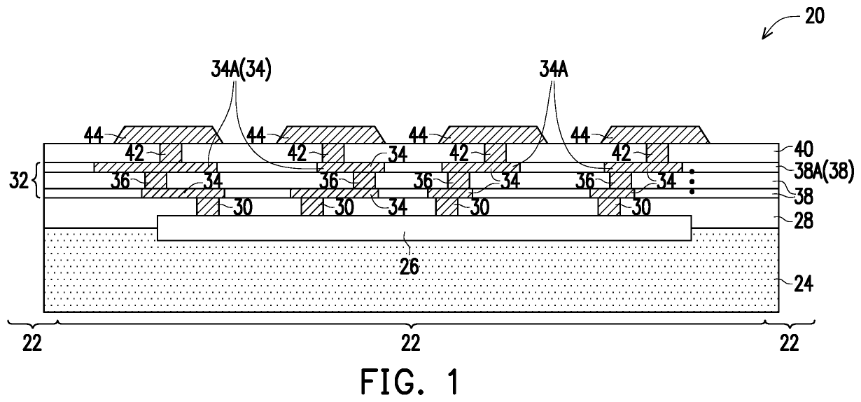

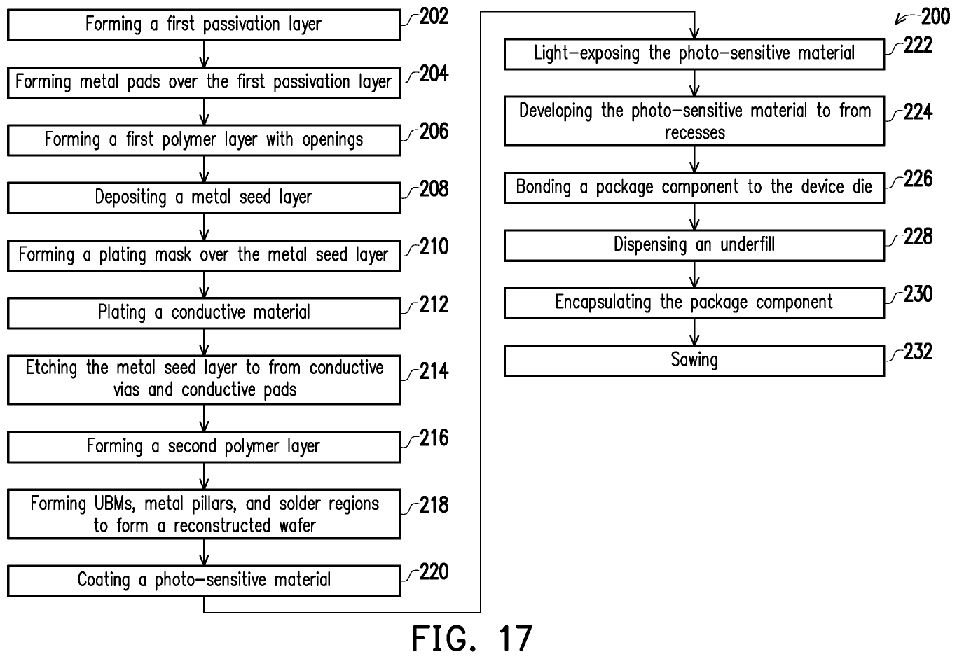

FIGS. 1-13 and 14A illustrate the cross-sectional views of intermediate stages in the formation of a package in accordance with some embodiments of the present disclosure. The corresponding processes are also reflected schematically in the process flow 200 as shown in FIG. 17.

FIG. 1 illustrates a cross-sectional view of package component 20. In accordance with some embodiments, package component 20 is or comprises a device wafer including active devices and possibly passive devices, which are represented as integrated circuit devices 26. Package component 20 may include a plurality of chips 22 (also referred to as (device) dies) therein, with one of device dies 22 being illustrated. In accordance with alternative embodiments, package component 20 is an interposer wafer, which is free from active devices, and may or may not include passive devices. In accordance with yet alternative embodiments, package component 20 is or comprises a package substrate strip, which includes core-less package substrates or cored package substrates having cores therein. In subsequent discussion, a device wafer is used as an example of package component 20, and package component 20 is accordingly referred to as wafer 20.

In accordance with some embodiments, wafer 20 includes semiconductor substrate 24 and the features formed at a top surface of semiconductor substrate 24. Semiconductor substrate 24 may be formed of or comprises crystalline silicon, crystalline germanium, silicon germanium, carbon-doped silicon, or a III-V compound semiconductor such as GaAsP, AlInAs, AlGaAs, GaInAs, GaInP, GaInAsP, or the like. Semiconductor substrate 24 may also be a bulk semiconductor substrate or a Semiconductor-On-Insulator (SOI) substrate. Shallow Trench Isolation (STI) regions (not shown) may be formed in semiconductor substrate 24 to isolate the active regions in semiconductor substrate 24. Although not shown, through-vias may (or may not) be formed to extend into semiconductor substrate 24, wherein the through-vias are used to electrically inter-couple the features on opposite sides of semiconductor substrate 24.

In accordance with some embodiments, wafer 20 includes integrated circuit devices 26, which are formed on the top surface of semiconductor substrate 24. Integrated circuit devices 26 may include transistors, resistors, capacitors, diodes, and the like in accordance with some embodiments. The details of integrated circuit devices 26 are not illustrated herein. In accordance with alternative embodiments, wafer 20 is used for forming interposers (which are free from active devices), and substrate 24 may be a semiconductor substrate or a dielectric substrate.

Inter-Layer Dielectric (ILD) 28 is formed over semiconductor substrate 24 and filling the spaces between the gate stacks of transistors (not shown) in integrated circuit devices 26. In accordance with some embodiments, ILD 28 is formed of Phospho Silicate Glass (PSG), Boro Silicate Glass (BSG), Boron-doped Phospho Silicate Glass (BPSG), Fluorine-doped Silicate Glass (FSG), silicon oxide, silicon oxynitride, silicon nitride, a low-k dielectric material, or the like. ILD 28 may be formed using spin coating, Flowable Chemical Vapor Deposition (FCVD), or the like. In accordance with some embodiments, ILD 28 is formed using a deposition method such as Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments, contact plugs 30 are formed of or comprise a conductive material selected from tungsten, aluminum, copper, titanium, tantalum, titanium nitride, tantalum nitride, alloys thereof, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Interconnect structure 32 is formed over ILD 28 and contact plugs 30. Interconnect structure 32 includes metal lines 34 and vias 36, which are formed in dielectric layers 38 (also referred to as Inter-metal Dielectrics (IMDs)). The metal lines at a same level are collectively referred to as a metal layer hereinafter. In accordance with some embodiments, interconnect structure 32 includes a plurality of metal layers including metal lines 34 that are interconnected through vias 36. Metal lines 34 and vias 36 may be formed of copper or copper alloys, and they can also be formed of other metals. In accordance with some embodiments, dielectric layers 38 are formed of low-k dielectric materials. The dielectric constants (k values) of the low-k dielectric materials may be lower than about 3.0, for example. Dielectric layers 38 may comprise a carbon-containing low-k dielectric material, Hydrogen SilsesQuioxane (HSQ), MethylSilsesQuioxane (MSQ), or the like. In accordance with some embodiments, the formation of dielectric layers 38 includes depositing a porogen-containing dielectric material in the dielectric layers 38 and then performing a curing process to drive out the porogen, and hence the remaining dielectric layers 38 are porous.

The formation of metal lines 34 and vias 36 in dielectric layers 38 may include single damascene processes and/or dual damascene processes. Each of the damascene structures may include a diffusion barrier layer and a copper-containing metallic material over the diffusion barrier layer. The diffusion barrier layer may include titanium, titanium nitride, tantalum, tantalum nitride, or the like.

Metal lines 34 include top conductive (metal) features (denoted as 34A) such as metal lines, metal pads, or vias. Top conductive features 34A are in a top dielectric layer (denoted as dielectric layer 38A), which is the top layer of dielectric layers 38. In accordance with some embodiments, top dielectric layer 38A is formed of a non-low-k dielectric material, which may include silicon nitride, Undoped Silicate Glass (USG), silicon oxide, or the like, or multi-layers thereof. In accordance with alternative embodiments, dielectric layer 38A is formed of a low-k dielectric material similar to the material of lower ones of dielectric layers 38. Dielectric layer 38A may also have a multi-layer structure including, for example, two USG layers and a silicon nitride layer in between. Top metal features 34A may also be formed of copper or a copper alloy, and may have a dual damascene structure or a single damascene structure.

Passivation layer 40 (sometimes referred to as passivation-1 or pass-1) is formed over interconnect structure 32. The respective process is illustrated as process 202 in the process flow 200 as shown in FIG. 17. In accordance with some embodiments, passivation layer 40 is formed of a non-low-k dielectric material having a dielectric constant greater than or equal to the dielectric constant of silicon oxide. Passivation layer 40 may be formed of or comprise an inorganic dielectric material, which may be selected from, and is not limited to, silicon nitride (SiN), silicon oxide (SiO₂), silicon oxy-nitride (SiON), silicon oxy-carbide (SiOC), silicon carbide (SiC), Un-doped Silicate Glass (USG), or the like, combinations thereof, and multi-layers thereof.

Passivation layer 40 is patterned in an etching process, and vias 42 are formed in passivation layer 40 to contact metal lines/pads 34A. Vias 42 may be formed through a single damascene process in accordance with some embodiments, or may formed along with metal pads 44.

Metal pads 44 are formed over and contacting vias 42. The respective process is illustrated as process 204 in the process flow 200 as shown in FIG. 17. Metal pads 44 may be electrically coupled to integrated circuit devices 26 through conductive features such as metal lines 34 and vias 36. In accordance with some embodiments, metal pads 44 are aluminum pads or aluminum-copper pads, while other metallic materials may be used. In accordance with some embodiments, metal pads 44 have an aluminum percentage greater than about 90 percent or 95 percent.

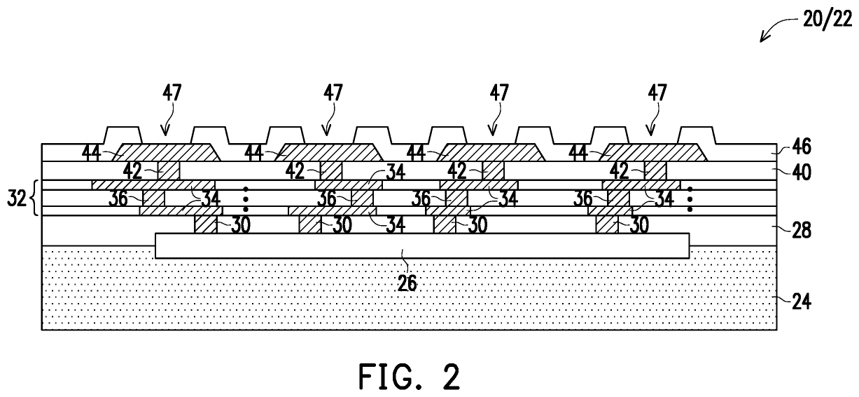

Referring to FIG. 2, passivation layer 46 is formed on metal pads 44. Passivation layer 46 may be a single layer or a composite layer, and may be formed of a non-porous material. In accordance with some embodiments, passivation layer 46 is a composite layer including a silicon oxide layer and a silicon nitride layer over the silicon oxide layer. Passivation layer 46 is then patterned through an etching process to form openings 47, so that passivation layer 46 may cover some portions of metal pads 44, and some other portions of the top surfaces of metal pads 44 are exposed through openings 47.

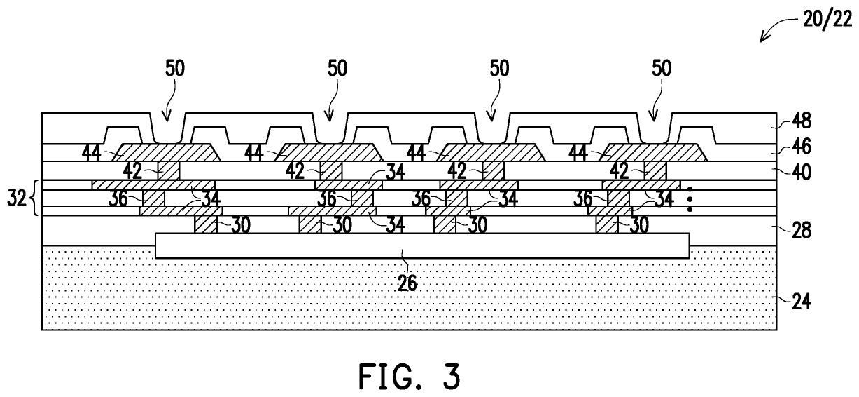

FIG. 3 illustrates the formation of dielectric layer 48. In accordance with some embodiments, dielectric layer 48 comprises a polymer, which may include polyimide, polybenzoxazole (PBO), benzocyclobutene (BCB), or the like. Accordingly, dielectric layer 48 is alternatively referred to as polymer layer 48, while it may also be formed of or comprises other dielectric materials such as inorganic dielectric materials. The respective process is illustrated as process 206 in the process flow 200 as shown in FIG. 17. The formation of polymer layer 48 may include spin-coating and then curing polymer layer 48. Openings 50 are formed in polymer layer 48, for example, through a light-exposure process followed by a development process.

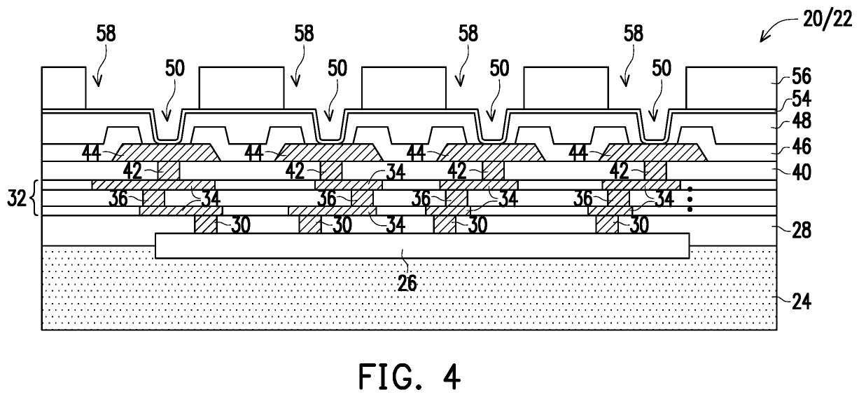

FIGS. 4 through 6 illustrate the formation of vias and the overlying conductive pads. Referring to FIG. 4, metal seed layer 54 is deposited over polymer layer. The respective process is illustrated as process 208 in the process flow 200 as shown in FIG. 17. Metal seed layer 54 is a conductive seed layer, and may be a metal seed layer. In accordance with some embodiments, metal seed layer 54 is a composite layer comprising two or more layers. For example, metal seed layer 54 may include a lower layer and an upper layer, wherein the lower layer may include a titanium layer, a titanium nitride layer, a tantalum layer, a tantalum nitride layer, or the like. The materials of the upper layer may include copper or a copper alloy. In accordance with alternative embodiments, metal seed layer 54 is a single layer, which may be a copper layer, for example. Metal seed layer 54 may be formed using Physical Vapor Deposition (PVD), Plasma Enhanced CVD (PECVD), Atomic Layer Deposition (ALD), or the like, while other applicable methods may also be used. Metal seed layer 54 is a conformal layer that extends into openings 50.

FIG. 4 also illustrates the formation of a patterned plating mask 56. The respective process is illustrated as process 210 in the process flow 200 as shown in FIG. 17. In accordance with some embodiments, plating mask 56 is formed of or comprises a photo resist. Plating mask 56 is patterned to form openings 58, through which some portions of the metal seed layer 54 are exposed. The patterning of plating mask 56 may include a light-exposure process and a development process.

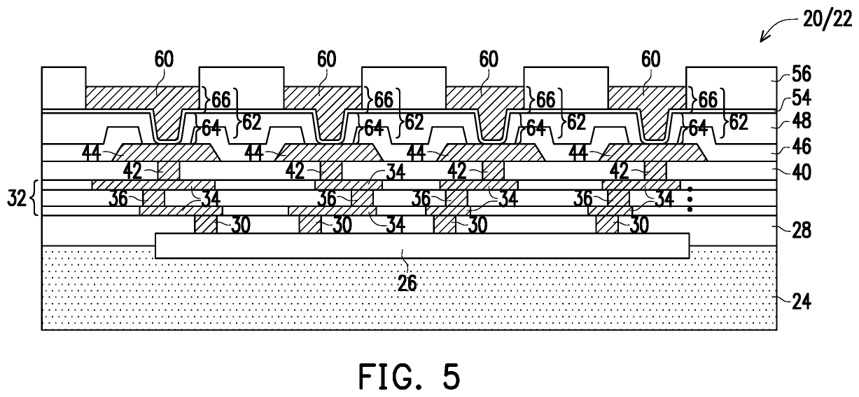

FIG. 5 illustrates the plating of conductive material (features) 60 into openings 58 and on metal seed layer 54. The respective process is illustrated as process 212 in the process flow 200 as shown in FIG. 17. In accordance with some embodiments, the formation of conductive features 60 includes a plating process, which may include an electrochemical plating process, an electroless plating process, or the like. The plating may be performed in a plating chemical solution. Conductive features 60 may include copper, aluminum, nickel, tungsten, or the like, alloys thereof, and/or multi-layers thereof. In accordance with some embodiments, conductive features 60 comprise copper, and are free from aluminum.

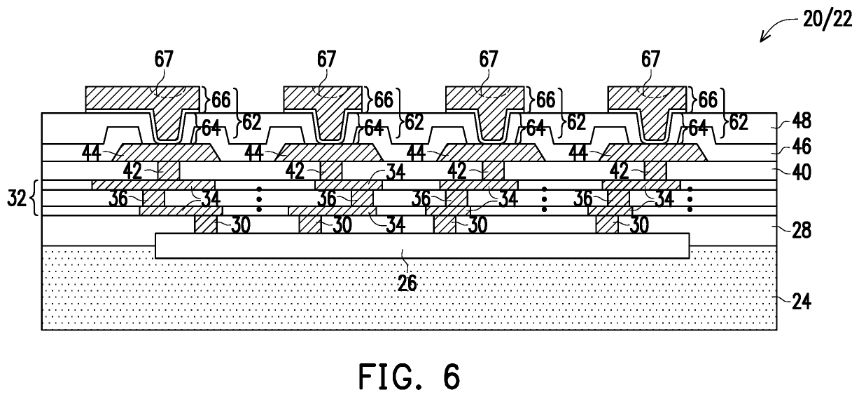

Next, the plating mask 56 as shown in FIG. 5 is removed, and the underlying portions of metal seed layer 54 are exposed. In a subsequent process, an etching process is performed to remove the exposed portions of metal seed layer 54. The respective process is illustrated as process 214 in the process flow 200 as shown in FIG. 17. The resulting structure is shown in FIG. 6. Throughout the description, conductive material and the corresponding underlying portions of metal seed layer 54 are collectively referred to Redistribution Lines (RDLs) 62. RDLs 62 may include via portions 64 (also referred to as vias or conductive vias) extending into polymer layer 48, and pad portions 66 (also referred to as conductive pads or metal pads) over polymer layer 48. In accordance with some embodiments, conductive pads 66 have planar top surfaces. In accordance with alternative embodiments, due to the plating process, the top surfaces of conductive pads 66 have recesses directly over the respective conductive vias 64, wherein dashed lines 67 are used to represent the recessed top surfaces of conductive pads 66.

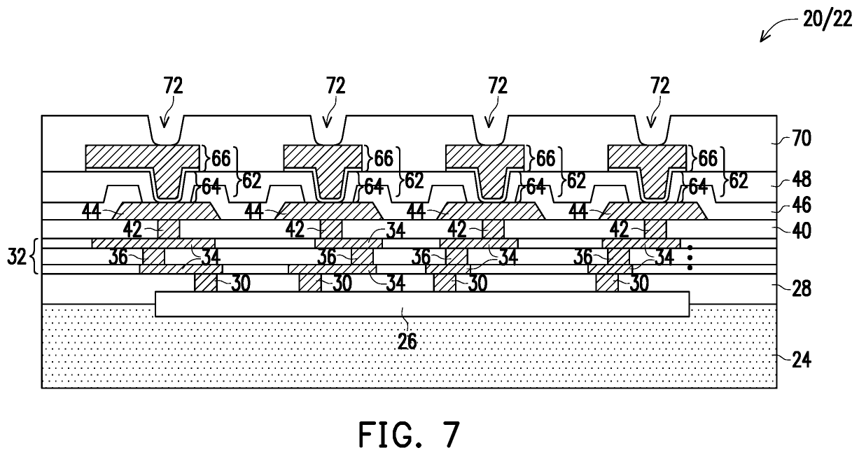

FIG. 7 illustrates the formation of dielectric layer 70. In accordance with some embodiments, dielectric layer 70 is a polymer (an organic) layer formed of or comprising a polymer (which may be photo-sensitive) such as polyimide, PBO, BCB, an epoxy, or the like. The respective process is illustrated as process 216 in the process flow 200 as shown in FIG. 17. In accordance with some embodiments, the formation of dielectric layer 70 includes coating the dielectric layer in a flowable form, and then performing a curing process to harden dielectric layer 70. A planarization process such as a CMP process or a mechanical grinding process may be (or may not be) performed to level the top surface of dielectric layer 70. Accordingly, dielectric layer 70 is also referred to as a planarization layer. In accordance with alternative embodiments, no planarization process is performed, and the top surface of dielectric layer 70 may have a topology reflecting the topology of the underlying features. For example, the portions of dielectric layer 70 directly over conductive pads 66 may have top surfaces higher than the top surfaces of the surrounding portions of dielectric layer 70.

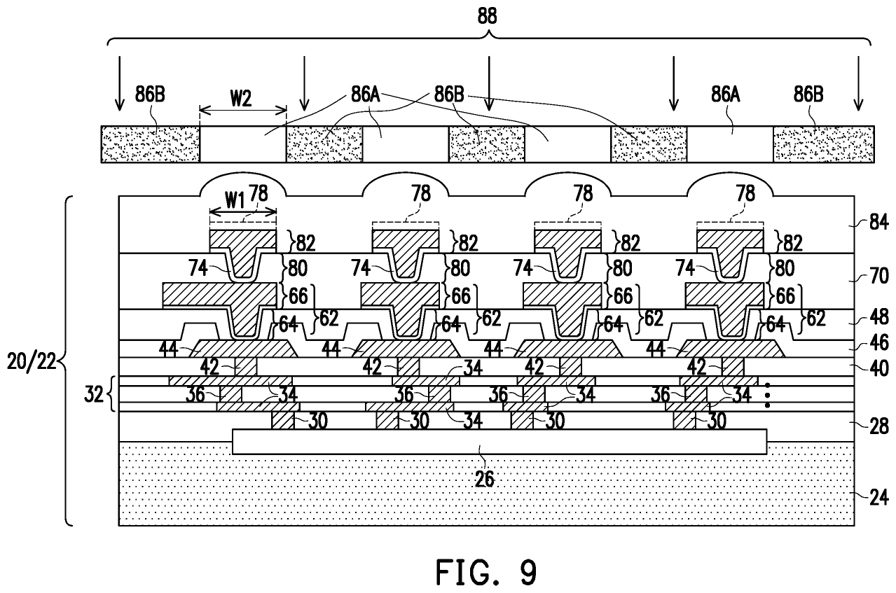

In a subsequent process, dielectric layer 70 is patterned, for example, through a light-exposure process and a photo-development process. Openings 72 are thus formed in dielectric layer 70, and conductive pads 66 are exposed. After the photo-development process, dielectric layer 70 is also post-baked, so that even if dielectric layer 70 receives the light used in the light-exposure of photo-sensitive layer 84 (FIG. 9) again in a subsequent process, dielectric layer 70 will not be patterned again.

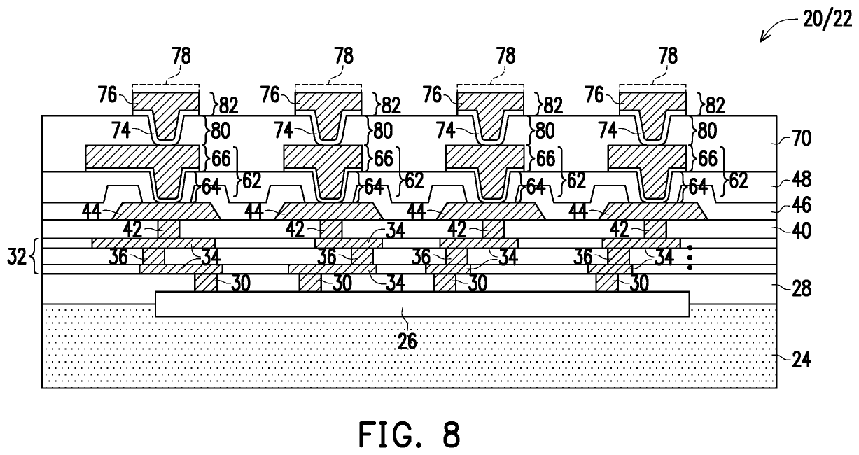

FIG. 8 illustrates the formation of UBMs, and the formation of metal pillars and solder regions (if formed) in accordance with some embodiments. The respective process is illustrated as process 218 in the process flow 200 as shown in FIG. 17. In an example formation process, metal seed layer 74 is deposited as a blanket layer, wherein FIG. 8 illustrates some remaining portions of the blanket seed layer 74. In accordance with some embodiments, metal seed layer 74 comprises a titanium layer and a copper layer over the titanium layer. In accordance with alternative embodiments, the entire metal seed layer 74 is formed of a homogeneous material such as copper or a copper alloy, with the homogenous material being in contact with dielectric layer 70 and the top surface of conductive pads 66. Metal seed layer 74 may be formed through PVD, ALD, or the like.

Next, conductive material 76 is plated. The process for plating conductive material 76 may include forming a patterned plating mask (not shown), and plating conductive material 76 in the openings in the patterned plating mask. The patterned plating mask may include a photoresist, and may be a single-layer plating mask, a double-layer plating mask, or a tri-layer plating mask. Conductive material 76 may comprise copper, nickel, palladium, aluminum, alloys thereof, and/or multi-layers thereof. In accordance with some embodiments, solder layers are also plated on conductive material 76 and in the openings in the patterned plating mask. The patterned plating mask is then removed.

In accordance with some embodiments, solder layers 78 are plated over conductive material 76. The plating is performed using the same plating mask for plating material 76. In accordance with alternative embodiments, no solder layer is plated. Accordingly, solder layers 78 are shown as being dashed to indicate the they may, or may not, be formed.

The blanket metal seed layer 74 is then etched, and the portions of metal seed layer 74 that are exposed after the removal of the plating mask are removed, while the portions of metal seed layer 74 directly underlying conductive material 76 are left. The resulting structure is shown in FIG. 8. The remaining portion of the metal seed layer are also referred to as Under-Bump Metallurgies (UBMs) 74. UBMs 74 and conductive material 76 in combination form vias 80 and electrical connectors 82. In subsequent discussion, electrical connectors 82 are also referred to as metal bumps 82. Metal bumps 82 protrude higher than the top surface of dielectric layer 70. In accordance with some embodiments in which solder layers 78 are also formed, a reflow process may be performed after the etching of metal seed layer, so that the solder layers 78 have rounded surfaces.

Referring to FIG. 9, dielectric layer 84 is formed. Dielectric layer 84 may be a photo-sensitive layer, which comprises photo-sensitive polymer such as polyimide, PBO, BCB, or the like. Dielectric layer 84 is coated on UBMs 74 through spin-coating. The respective process is illustrated as process 220 in the process flow 200 as shown in FIG. 17. After the coating, photo-sensitive layer 84 is pre-baked to drive out the solvent therein.

The top surfaces of photo-sensitive layer 84 are higher than the tops surfaces of metal bumps 82. It is appreciated that since metal bumps 82 protrude higher than the top surface of dielectric layer 70, the top surface of photo-sensitive layer 84 may not be planar, and the portions of photo-sensitive layer 84 directly over metal bumps 82 may be higher than other portions. In accordance with some embodiments, the top surface of photo-sensitive layer 84 is planarized in a polishing process such as a CMP process and/or a mechanical grinding process. As a result, the entire top surface of photo-sensitive layer 84 is planar. In accordance with alternative embodiments, the planarization process is not performed. As a result, the top surface of photo-sensitive layer 84 include higher (raised) portions directly over metal bumps 82, and lower portions that are laterally offset from metal bumps 82.

In accordance with alternative embodiments, dielectric layer 84 may be an inorganic dielectric layer, which may comprise silicon oxide, silicon nitride, silicon oxynitride, silicon carbide, silicon oxycarbide, or the like. Accordingly, dielectric layer 84 will be patterned by using processes including forming a patterned etching mask (such as photoresist) over dielectric layer 84, and then etching dielectric layer 84 using the patterned etching mask to define patterns.

In accordance with some embodiments in which dielectric layer 84 comprises a light-sensitive material, a light-exposure process 88 is performed to light-expose photo-sensitive layer 84. The respective process is illustrated as process 222 in the process flow 200 as shown in FIG. 17. The light-exposure process 88 is performed using lithography mask 86, which includes transparent patterns 86A allowing light to pass through and opaque patterns 86B for blocking the light. Photo-sensitive layer 84 may be formed of a positive photo-sensitive material, wherein the light-exposed parts will be removed when developed, while the un-exposed parts will remain. Alternatively, photo-sensitive layer 84 may be formed of a negative photo-sensitive material, wherein the unexposed parts will be removed when developed, while the light-exposed parts will remain. FIG. 9 illustrates an example in which photo-sensitive layer 84 is positive, and the transparent patterns 86A in lithography mask 86 are directly over metal bumps 82. In accordance with other embodiments, a negative photo-sensitive layer 84 may be used, and the transparent patterns and opaque patterns will be inversed than the patterns shown in FIG. 9.

In the illustrated example, the patterns 86A directly over metal bumps 82 have lateral dimensions W2 greater than the lateral dimensions W1 of metal bumps 82. Furthermore, patterns 86A may extend laterally beyond the edges of metal bumps 82. In accordance with some embodiments, patterns 86A may extend laterally beyond the edge of metal bumps 82 in all lateral directions (when viewed from top) that are parallel to the top surface of photo-sensitive layer 84. In accordance with alternative embodiments, patterns 86A may extend laterally beyond the edge of metal bumps 82 in some, but not all, lateral directions that are parallel to the top surface of photo-sensitive layer 84.

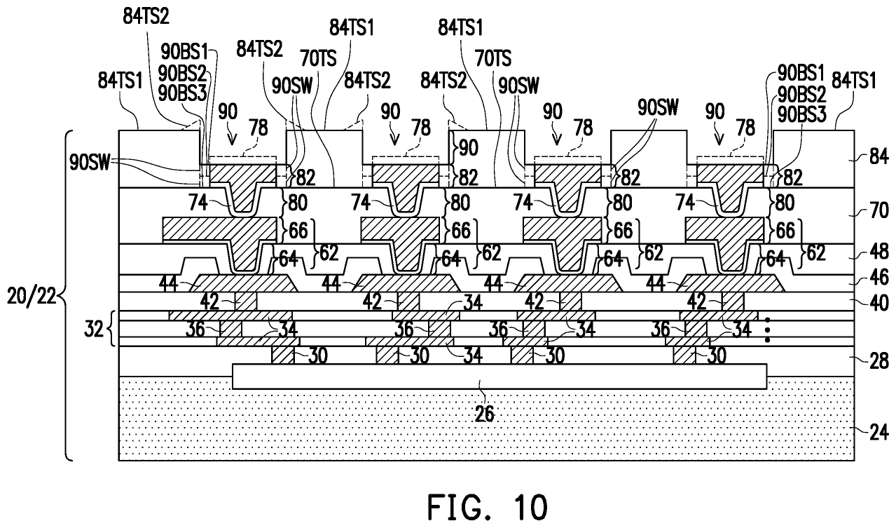

In accordance with alternative embodiments, patterns 86A may have their edges vertically aligned to the respective edges of metal bumps 82, so that the subsequently formed recesses 90 (FIG. 10) have boundaries vertically aligned to the respective edges of the underlying metal bumps 82. In accordance with yet alternative embodiments, patterns 86A may have their edges laterally recessed from the respective edges of metal bumps 82, so that the subsequently formed recesses 90 (FIG. 10) have boundaries laterally recessed from the respective edges of the underlying metal bumps 82, and hence the lateral dimensions of the recesses are smaller than the lateral recesses of the underlying metal bumps 82.

Referring to FIG. 10, the exposed photo-sensitive layer 84 is developed, and recesses 90 are formed in photo-sensitive layer 84, revealing metal bumps 82. The respective process is illustrated as process 224 in the process flow 200 as shown in FIG. 17. In accordance with some embodiments, the bottom surfaces 90BS1 of recesses 90 are coplanar with (or substantially coplanar with, for example, with height difference being smaller than about 1 μm or about 0.5 μm) the top surfaces of metal bumps 82. Accordingly, there are some portions of photo-sensitive layer 84 directly underlying recesses 90. This may be achieved by controlling the focus depth in the light-exposure process, controlling the light intensity in the light-exposure process, controlling the duration of the light-exposure, and/or the like.

In accordance with alternative embodiments, the bottom surfaces of photo-sensitive layer 84 are lower than the top surface of metal bumps 82 and higher than the top surface 70TS of dielectric layer 70. This may also be achieved by controlling the focus depth in the light-exposure process, controlling the light intensity, controlling the duration of the light-exposure, and/or the like. The bottom surfaces of the respective recesses 90 are shown using dashed lines 90BS2.

In accordance with yet alternative embodiments, the top surface 70TS of dielectric layer 70 are exposed to the recesses 90. The corresponding bottom surfaces of recesses 90 are marked as 90BS3. The sidewalls of the corresponding recesses 90 are also shown as 90SW. Since dielectric layer 70 has been post-baked, it is no longer affected by the light exposure and development processes for patterning photo-sensitive layer 84. Accordingly, although dielectric layer 70 may receive the light used for light-exposure process 88 (FIG. 9), the top surface 70TS of dielectric layer 70 will not be recessed even if dielectric layer 70 is exposed to recesses 90.

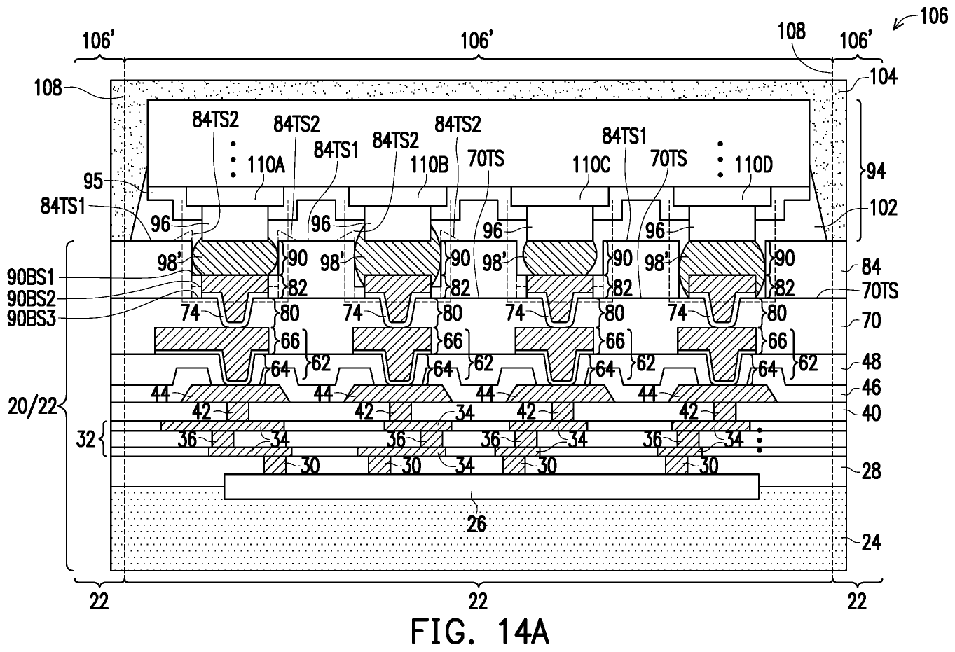

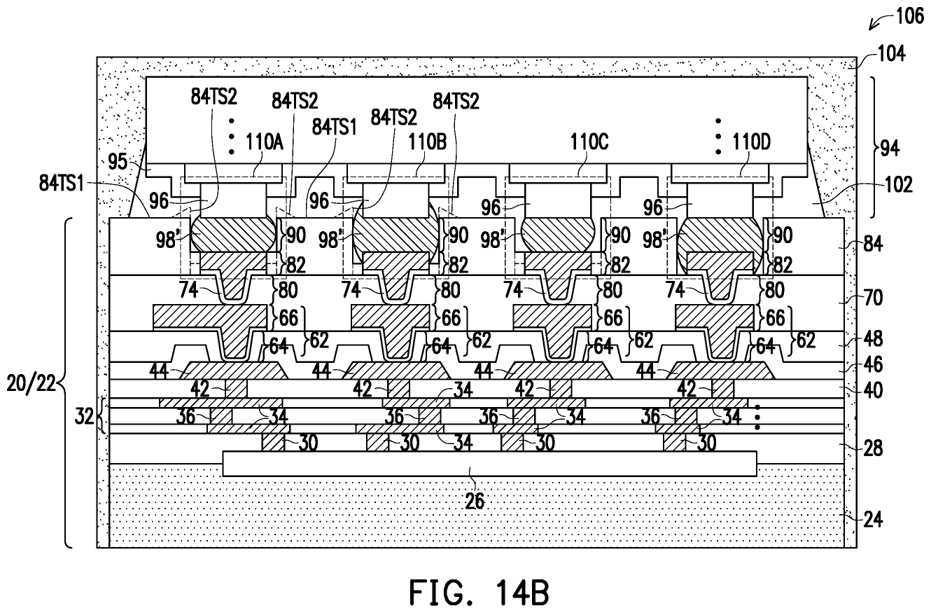

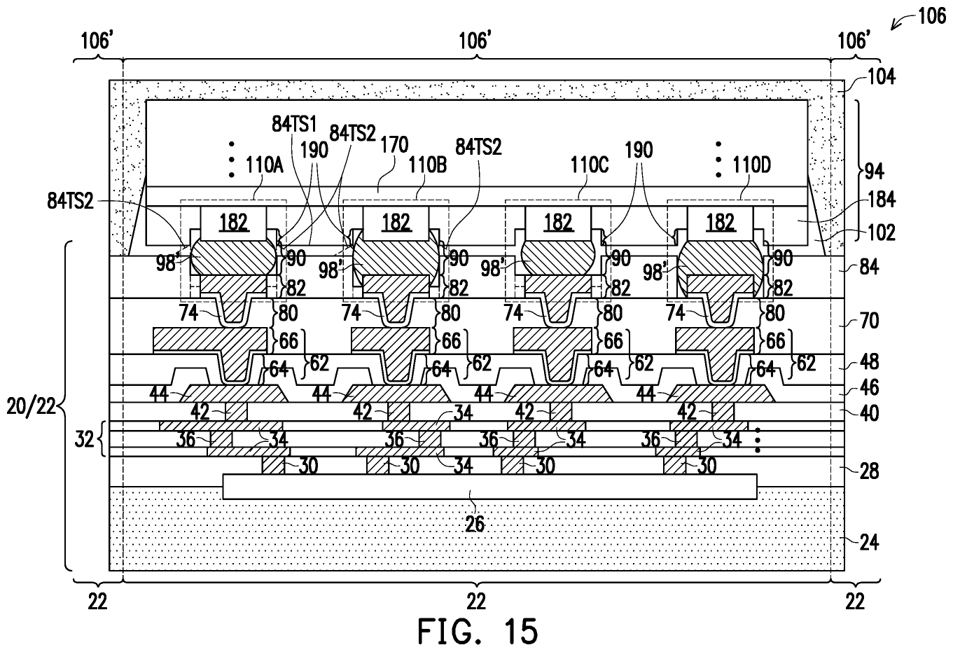

As addressed in preceding paragraphs, photo-sensitive layer 84 may be, or may not be, planarized. In accordance with the embodiments in which photo-sensitive layer 84 is planarized, the top surface of photo-sensitive layer 84 (except the top surfaces underlying recesses 90) are coplanar, and are shown as top surface 84TS1. In accordance with alternative embodiment in which photo-sensitive layer 84 is not planarized, the top surfaces 84TS2 of the portions of photo-sensitive layer 84 encircling recesses 90 may be raised to be higher than the top surfaces 84TS1 of the portions of photo-sensitive layer 84 between the raised portions. The raised top surfaces 84TS2 are shown using dashed lines. The top surfaces 84TS1 and 84TS2 will also be observable in the final package as shown in FIGS. 14A, 14B and 15. In subsequent figures, the raised top surface 84TS2 may only be illustrated for one of the recesses 90, while other recesses 90 may also have raised top surfaces 84TS2.

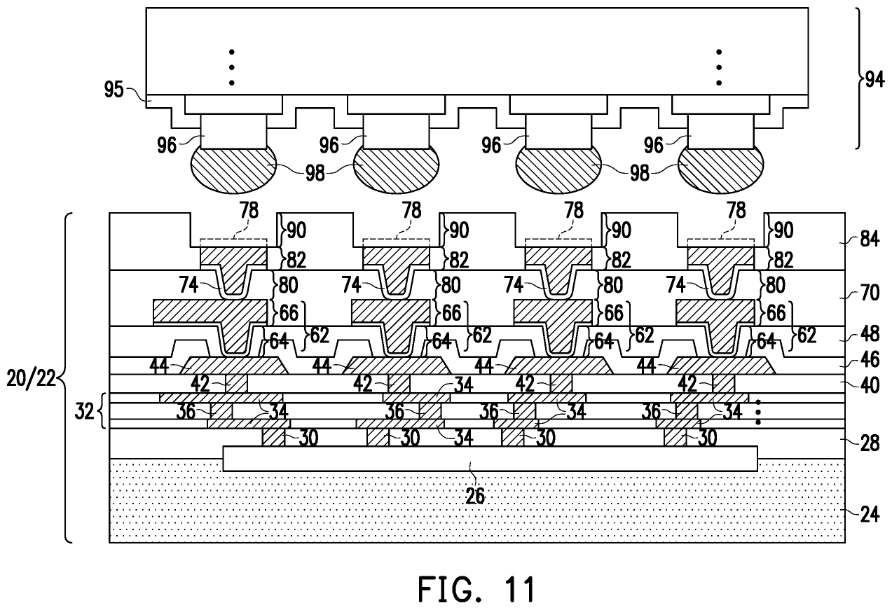

Referring to FIG. 11, package component 94 is aligned to wafer 20. Although one package component 94 is shown, there may be a plurality of package components 94, each being bonded to one of device dies 22. In accordance with some embodiments, dielectric layer 95 is formed on the surface of package component 94. Dielectric layer 95 may be formed of solder mask, an organic dielectric material, an inorganic dielectric material, or the like. In accordance with some embodiments, package component 94 is or comprises a device die (including active devices therein), an interposer, a package substrate, a printed circuit board, a package, or the like. Throughout the description, package component 94 is also referred to as top die. Package component 94 includes electrical connectors 96, which may be metal pillars (such as copper pillars), bond pads, or the like. Electrical connectors 96 are formed at the surface of package component 94, and may or may not protrude beyond the bottom surface of dielectric layer 95. Solder regions 98 are formed on electrical connectors 96. In the alignment process, solder regions 98 and electrical connectors 96 are aligned to metal bumps 82.

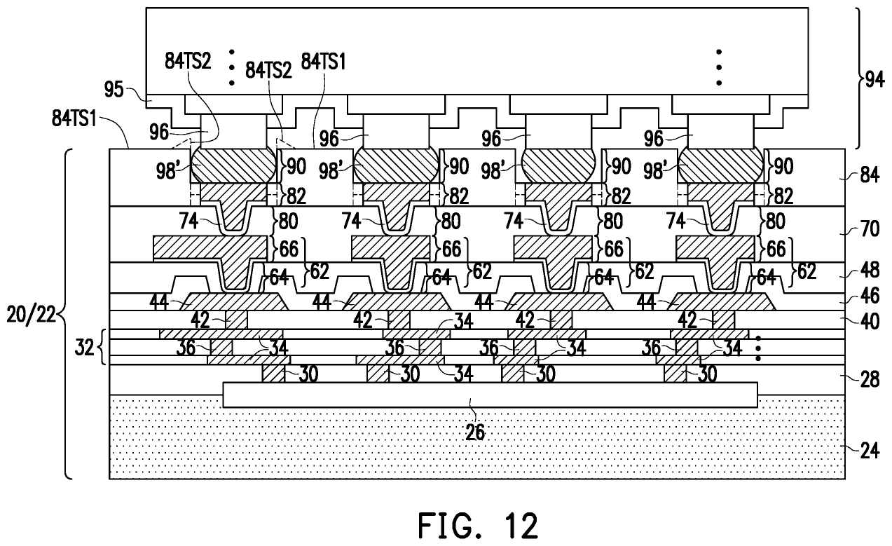

Package component 94 is then placed on device die 22 in wafer 20. Solder regions 98 are inserted into recesses 90. Next, a reflow process is performed to reflow solder regions 98 and solder layers 78 (if formed), so that package component 94 is bonded to device die 22. The respective process is illustrated as process 226 in the process flow 200 as shown in FIG. 17. The resulting solder regions are referred to as solder regions 98′, as shown in FIG. 12. In the bonding process, due to the confinement of solder regions 98′ and electrical connectors 96 by the sidewalls of recesses 90, the bonding process is self-aligned.

After solder regions 98′ are solidified, the bottom surfaces of electrical connectors 96 may be higher than, level with, or lower than, the top surfaces 84TS1 and/or 84TS2 of photo-sensitive layer 84. When the bottom surfaces of electrical connectors 96 are lower than the top surface 84TS2 of photo-sensitive layer 84, the bottom portions of electrical connectors 96 are inserted into recesses 90 also.

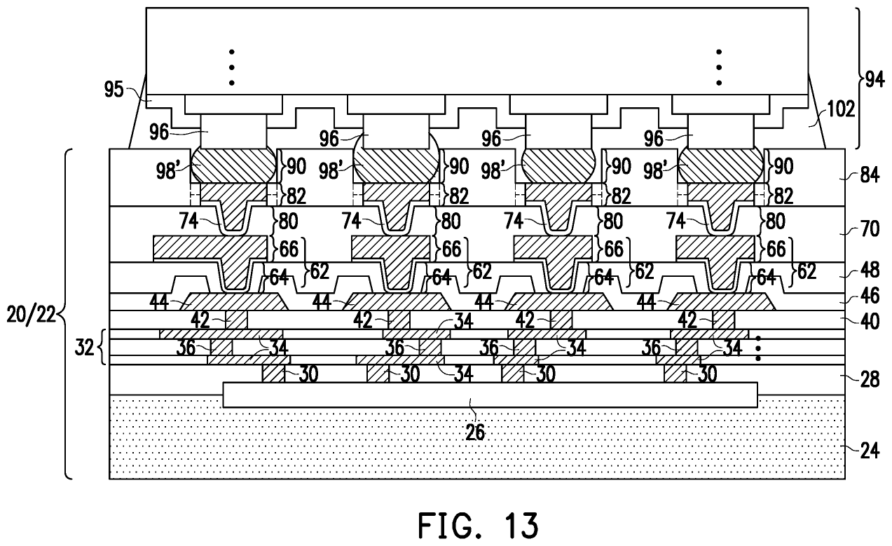

Referring to FIG. 13, underfill 102 is dispensed between wafer 20 and package component 94. The respective process is illustrated as process 228 in the process flow 200 as shown in FIG. 17. In accordance with some embodiments, underfill 102 fills recesses 90, either partially or fully. For example, the upper portions of recesses 90 not occupied by solder regions 98′ may be filled with underfill 102. When solder regions 98′ blocks underfill 102 from flowing into the bottom portions of recesses 90, the bottom portions of recesses 90 may be air gaps. Otherwise, the bottom portions of recesses 90 are also filled with underfill 102.

In a subsequent process, as shown in FIG. 14A, encapsulant 104 is applied to encapsulate package component 94. The respective process is illustrated as process 230 in the process flow 200 as shown in FIG. 17. Reconstructed wafer 106 is thus formed. In accordance with some embodiments, as also shown in FIG. 14A, reconstructed wafer 106 is sawed along scribe lines 108 to separate reconstructed wafer 106 into discrete packages 106′. The respective process is illustrated as process 232 in the process flow 200 as shown in FIG. 17. The discrete packages 106′ are identical to each other, each including device die 22 and the package component 94. In the resulting packages 106′, the edges of encapsulant 104 are vertically aligned to the edges of device dies 22.

As discussed in preceding embodiments, recesses 90 may have bottom surfaces level with or lower than the top surfaces of metal bumps 92. Also, the top surface of dielectric layer 70 may, or may not, be exposed to recesses 90. In accordance with some embodiments, the bottoms of all recesses 90 are at the same level, and the bottom levels of the recesses 90 may be discussed in preceding paragraphs. In accordance with alternative embodiments, the bottom levels of the recesses 90 in the same device die (and same wafer 20) may be at different levels.

FIG. 14A illustrates four possible bond structures 110A, 110B, 110C, and 110D, each including the corresponding metal bump 82, solder region 98′, electrical connector 96, and the recess 90. One package 96′ (and reconstructed wafer 96) may include a one or more of bond structures 110A, 110B, 110C, and 110D therein in any combination. The different bond structures in the same package/wafer may be caused by process variation, or may be intentionally formed. It is also noted that the features shown in bond structures 110A, 110B, 110C, and 110D are some of the possible combinations of features, which possible features include (and are not limited to) the bottom levels of recesses 90, whether solder regions 98′ contact the sidewalls of photo-sensitive layer 84, whether solder region 98′ extend on the sidewalls of metal bumps 82, and whether solder region 98′ extend on the sidewalls of electrical connectors 96. All other possible combinations are also contemplated whenever feasible.

In bond structure 110A, the bottom of recess 90 may be at any level marked as 90BS2, and 90BS3. An entirety of solder region 98′ is over, and is in contact with, the top surface of, metal bump 92. Solder region 98′ is also underlying, and contacting the bottom surface of, electrical connector 96, and may or may not extend on the sidewalls of electrical connector 96.

In bond structure 110B, the bottom of recess 90 may be between the top surface of metal bump 82 and the top surface 70TS of dielectric layer 70. In accordance with some embodiments, an entirety of solder region 98′ is over metal bump 92. In accordance with alternative embodiments as illustrated, solder region 98′ extends lower than the top surface metal bump 92 and contacts the sidewalls of metal bump 92. Solder region 98′ may also contact the bottom surface and the sidewalls of electrical connector 96, or may be limited to be under the bottom surface of electrical connector 96. Solder region 98′ may (or may not) extend to the sidewalls of photo-sensitive layer 84, which sidewalls are exposed to recess 90.

In bond structure 110C, solder region 98′ is spaced apart from the sidewalls of photo-sensitive layer 84. Recess 90 extends to the top surface of dielectric layer 70 or may extend lower, as shown by dashed lines. Solder region 98′ contacts the top surface of metal bump 92, and may or may not, contact the sidewalls of metal bump 92 to form vertical interfaces. Solder region 98′ may also contact the bottom surface, and may or may not contact the sidewalls, of electrical connector 96.

In bond structure 110D, the top surface 70TS of dielectric layer 70 is exposed to recess 90. Solder region 98′ contacts the sidewalls of metal bump 92 to form vertical interfaces. Solder region 98′ may extend to top surface 70TS, or may be higher than top surface 70TS. Solder region 98′ is also underlying, and contacts the bottom surface of, electrical connector 96.

FIG. 14B illustrates reconstructed wafer 106 in accordance with alternative embodiments. In these embodiments, the resulting packages are used at wafer level. For example, in high-performance applications such as Artificial Intelligence (AI) applications, the reconstructed wafer 106 is used without being sawed, and reconstructed wafer 106 may be fixed on a fixture, and is power up when not sawed. In reconstructed wafer 106, encapsulant 104 may contact the sidewalls of wafer 20.

FIG. 15 illustrates reconstructed wafer 96 and the sawed packages 96′ in accordance with alternative embodiments. Package component 94 in accordance with these embodiments may include dielectric layer 170, metal bump 182, photo-sensitive layer 184, and recesses 190. The structures, the materials, and the formation processes of dielectric layer 170, metal bump 182, photo-sensitive layer 184, and recesses 190 may be the same as the corresponding dielectric layer 70, metal bump 82, photo-sensitive layer 84, and recesses 90 in wafer 20, hence and the details are not repeated herein. The relationship of dielectric layer 170, metal bump 182, photo-sensitive layer 184, and recesses 190 may also be similar to what has been discussed referring to bond structures 110A, 110B, 110C, and 110D. In accordance with some embodiments, recesses 190 are aligned with, and may have the lateral dimensions equal to, greater than, or smaller than the lateral dimensions of the corresponding underlying recesses 90.

In accordance with some embodiments, as shown in FIGS. 14A, 14B, and 15, the reconstructed wafer 106 and packages 106′ include dielectric layer 70, and photo-sensitive layer 84 over dielectric layer 70. Both of dielectric layer 70 and photo-sensitive layer 84 may be formed of materials selected from the same group (or different groups) of materials such as polyimide, PBO, BCB, and the like. The material of dielectric layer 70 may be the same as, or different from, the material of photo-sensitive layer 84. In accordance with some embodiments, regardless of whether dielectric layer 70 and photo-sensitive layer 84 are formed of the same material or different materials, the interface between dielectric layer 70 and photo-sensitive layer 84 may be distinguishable.

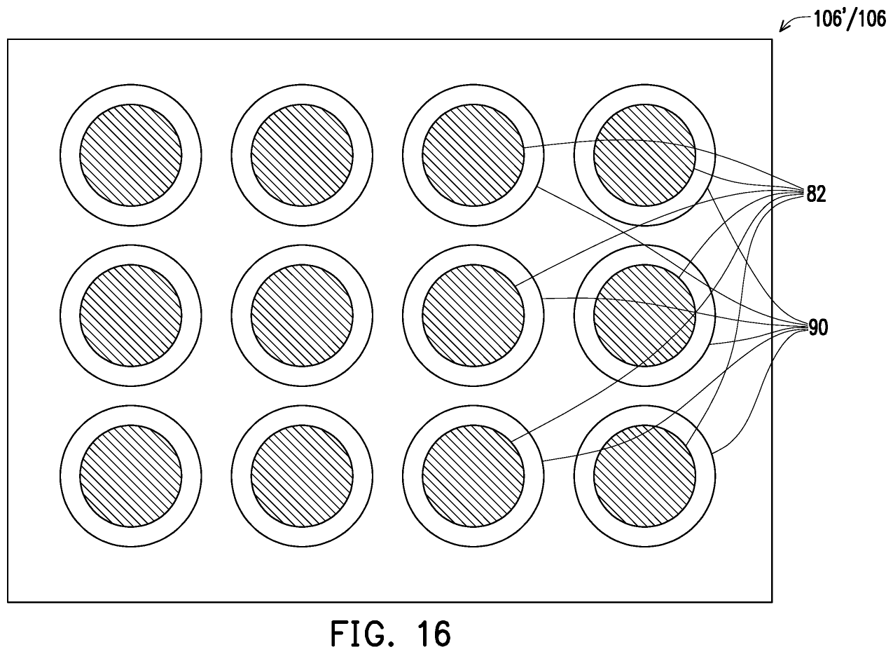

FIG. 16 illustrates a top view of reconstructed wafer 106 and packages 106′ (denoted as 106/106′) in accordance with some embodiments. There may be a plurality of metal bumps 82, which may be arranged as an array or any other pattern. Recesses 90, which may be filled with solder regions and possibly underfill, may extend laterally beyond the edges of metal bumps 82. Alternatively, the recesses 90 may be narrower than, or have the same top-view shape and top-view sizes as, the respective underlying metal bumps 82.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming a dielectric layer (which may be a photo-sensitive layer) and recessing the dielectric layer to form recesses, the recesses may hold solder regions and limit the lateral expansion of the solder regions. The solder regions thus may have small pitches without the risk of bridging.

In accordance with some embodiments of the present disclosure, a method comprises forming a first package component comprising forming a first dielectric layer comprising a first top surface; forming a first conductive feature, wherein the first conductive feature comprises a via embedded in the first dielectric layer; and a metal bump comprising a second top surface higher than the first top surface of the first dielectric layer; dispensing a photo-sensitive layer, wherein the photo-sensitive layer covers the metal bump; and performing a photolithography process to form a recess in the photo-sensitive layer, wherein the metal bump is exposed to the recess, and wherein the photo-sensitive layer comprises a third top surface higher than the metal bump; and bonding a second package component to the first package component, wherein a solder region extends into the recess to bond the metal bump to a second conductive feature in the second package component.

In an embodiment, the performing the photolithography process comprises: performing a light-exposure process on the photo-sensitive layer; and developing the photo-sensitive layer to remove a portion of the photo-sensitive layer covering the metal bump. In an embodiment, the recess extends laterally beyond edges of the metal bump, and wherein a portion of the photo-sensitive layer is directly underlying the recess. In an embodiment, a sidewall of the metal bump is exposed to the recess, and wherein the solder region extends to a level lower than the second top surface of the metal bump to contact the sidewall of the metal bump. In an embodiment, the first dielectric layer comprises an additional photo-sensitive layer. In an embodiment, the recess extends to the first top surface of the first dielectric layer, and wherein in the photolithography process, the first dielectric layer is not patterned.

In an embodiment, the first dielectric layer and the photo-sensitive layer are formed of a same photo-sensitive material. In an embodiment, the method further comprises, after the photo-sensitive layer is dispensed and before the photolithography process is performed, performing a planarization process on the photo-sensitive layer. In an embodiment, at a time the photolithography process is started, the third top surface of the photo-sensitive layer comprises a lower portion laterally offset from the metal bump; and a higher portion directly over the metal bump, wherein the higher portion is higher than the lower portion. In an embodiment, after the photolithography process is finished, the third top surface of the photo-sensitive layer comprises a raised portion surrounding the recess, and wherein the raised portion is a part of the higher portion.

In accordance with some embodiments of the present disclosure, a structure comprises a first package component comprising a dielectric layer; a conductive feature, wherein the conductive feature comprises a via extending into the dielectric layer; and a metal bump protruding higher than a first top surface of the dielectric layer; and a photo-sensitive structure extending from a lower level to a higher level, wherein the lower level is lower than a second top surface of the metal bump, and the higher level is higher than the second top surface of the metal bump; and a solder region extending into the photo-sensitive structure to join to the metal bump, wherein the solder region extends laterally beyond edges of the metal bump. In an embodiment, the photo-sensitive structure comprises a photo-sensitive material selected from the group consisting of polyimide, PBO, and BCB.

In an embodiment, both of the dielectric layer and the photo-sensitive structure comprise photo-sensitive materials. In an embodiment, the dielectric layer and the photo-sensitive structure are formed of a same photo-sensitive material, and are in contact with each other to form a distinguishable interface in between. In an embodiment, the solder region contacts a sidewall of the photo-sensitive structure. In an embodiment, the structure further comprises a second package component comprising an additional metal bump, wherein the additional metal bump is bonded to the metal bump through the solder region, and wherein a bottom surface of the additional metal bump is level with or lower than the first top surface of the dielectric layer.

In accordance with some embodiments of the present disclosure, a structure comprises a device die comprising a first photo-sensitive structure; a first metal bump and a second metal bump neighboring each other and extending higher than the first photo-sensitive structure; a second photo-sensitive structure over and contacting the first photo-sensitive structure, wherein the second photo-sensitive structure comprises a first recess and a second recess, with the first metal bump and the second metal bump being underlying the first recess and the second recess, respectively; a first solder region and a second solder region extending into the first recess and the second recess, respectively, wherein a portion of the second photo-sensitive structure separates the first solder region from the second solder region; and a second package component comprising a first conductive feature bonding to the first metal bump through the first solder region; and a second conductive feature bonding to the second metal bump through the second solder region.

In an embodiment, the first recess is wider than the first metal bump. In an embodiment, the second photo-sensitive structure comprises a lower portion directly underlying the first recess, and wherein the lower portion has a top surface level with the first metal bump. In an embodiment, the first photo-sensitive structure and the second photo-sensitive structure are formed of a same photo-sensitive material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first package component comprising:
forming a first dielectric layer comprising a first top surface;
forming a first conductive feature, wherein the first conductive feature comprises:
a via extending into the first dielectric layer; and
a metal bump comprising a second top surface higher than the first top surface of the first dielectric layer;
dispensing a photo-sensitive layer, wherein the photo-sensitive layer covers the metal bump; and
performing a photolithography process to form a recess in the photo-sensitive layer, wherein the metal bump is exposed to the recess, and wherein the photo-sensitive layer comprises a third top surface higher than the metal bump; and
bonding a second package component to the first package component, wherein a solder region extends into the recess to bond the metal bump to a second conductive feature in the second package component.

2. The method of claim 1, wherein the performing the photolithography process comprises:
performing a light-exposure process on the photo-sensitive layer; and
developing the photo-sensitive layer to remove a portion of the photo-sensitive layer covering the metal bump.

3. The method of claim 1, wherein the recess extends laterally beyond edges of the metal bump, and wherein a portion of the photo-sensitive layer is directly underlying the recess.

4. The method of claim 1, wherein a sidewall of the metal bump is exposed to the recess, and wherein the solder region extends to a level lower than the second top surface of the metal bump to contact the sidewall of the metal bump.

5. The method of claim 1, wherein the first dielectric layer comprises an additional photo-sensitive layer.

6. The method of claim 5, wherein the recess extends to the first top surface of the first dielectric layer, and wherein in the photolithography process, the first dielectric layer is not patterned.

7. The method of claim 6, wherein the first dielectric layer and the photo-sensitive layer are formed of a same photo-sensitive material.

8. The method of claim 1 further comprising, after the photo-sensitive layer is dispensed and before the photolithography process is performed, performing a planarization process on the photo-sensitive layer.

9. The method of claim 1, wherein at a time the photolithography process is started, the third top surface of the photo-sensitive layer comprises:
a lower portion laterally offset from the metal bump; and
a higher portion directly over the metal bump, wherein the higher portion is higher than the lower portion.

10. The method of claim 9, wherein after the photolithography process is finished, the third top surface of the photo-sensitive layer comprises a raised portion surrounding the recess, and wherein the raised portion is a part of the higher portion.

11. A structure comprising:
a first package component comprising:
a dielectric layer;
a conductive feature, wherein the conductive feature comprises:
a via embedded in the dielectric layer; and
a metal bump protruding higher than a first top surface of the dielectric layer; and
a photo-sensitive structure extending from a lower level to a higher level, wherein the lower level is lower than a second top surface of the metal bump, and the higher level is higher than the second top surface of the metal bump; and
a solder region extending into the photo-sensitive structure to join to the metal bump, wherein the solder region extends laterally beyond edges of the metal bump.

12. The structure of claim 11, wherein the photo-sensitive structure comprises a photo-sensitive material selected from the group consisting of polyimide, polybenzoxazole (PBO), and benzocyclobutene (BCB).

13. The structure of claim 12, wherein both of the dielectric layer and the photo-sensitive structure comprise photo-sensitive materials.

14. The structure of claim 13, wherein the dielectric layer and the photo-sensitive structure are formed of a same photo-sensitive material, and are in contact with each other to form a distinguishable interface in between.

15. The structure of claim 11, wherein the solder region contacts a sidewall of the photo-sensitive structure.

16. The structure of claim 11 further comprising a second package component comprising an additional metal bump, wherein the additional metal bump is bonded to the metal bump through the solder region, and wherein a bottom surface of the additional metal bump is level with or lower than the first top surface of the dielectric layer.

17. A structure comprising:
a device die comprising:
a first photo-sensitive structure;
a first metal bump and a second metal bump neighboring each other and extending higher than the first photo-sensitive structure;
a second photo-sensitive structure over and contacting the first photo-sensitive structure;
a first solder region and a second solder region extending into the second photo-sensitive structure, wherein a portion of the second photo-sensitive structure separates the first solder region from the second solder region, and wherein the first metal bump and the second metal bump are underlying a first upper portion of the first solder region and a second upper portion of the second solder region, respectively; and
a second package component comprising:
a first conductive feature bonding to the first metal bump through the first solder region; and
a second conductive feature bonding to the second metal bump through the second solder region.

18. The structure of claim 17, wherein the first solder region is wider than the first metal bump.

19. The structure of claim 17, wherein the second photo-sensitive structure comprises a lower portion directly underlying the first upper portion of the first solder region, and wherein the lower portion has a top surface level with the first metal bump.

20. The structure of claim 17, wherein the first photo-sensitive structure and the second photo-sensitive structure are formed of a same photo-sensitive material.
